(19) United States
(12) Patent Application Publication
(10) Pub. No.: US 2012/0250416 A1
(43) Pub. Date: Oct. 4, 2012

(54) SEMICONDUCTOR MEMORY DEVICE

(75) Inventor: Yasuhiro SHIMURA, Kanagawa-ken (JP)

(73) Assignee: KABUSHIKI KAISHA TOSHIBA, Tokyo (JP)

(21) Appl. No.: 13/433,956

(22) Filed: Mar. 29, 2012

(30) Foreign Application Priority Data
Mar. 30, 2011 (JP) 2011-076433

(51) Int. Cl. G11C 16/04

(52) U.S. Cl. 365/185.18

(57) ABSTRACT

A semiconductor memory device includes: a memory cell array including plural memory cells; a first word line connected to a control gate of a first memory cell; a second word line connected to a control gate of a second memory cell and neighboring the first word line on one side; a third word line connected to a control gate of a third memory cell and neighboring the first word line on the opposite side to the one side; and a control circuit configured to read data from the first word line under a condition in which the memory cell connected to the second word line holds data while the memory cell connected to the third word line does not hold data, and to set a first voltage applied to the third word line to be lower than a second voltage applied to the second word line.

### CROSS-REFERENCE TO RELATED APPLICATIONS

This application is based upon and claims the benefit of priority from the prior Japanese Patent Application No. 2011-076433, filed Mar. 30, 2010, the entire contents of which are incorporated herein by reference.

### FIELD

Embodiments described herein relate generally to a semiconductor memory device, and more particularly to a semiconductor memory device including electrically erasable and programmable nonvolatile memory cells.

### BACKGROUND

As semiconductor memory devices, there are known NAND flash memories that are electrically erasable and programmable and capable of achieving high integration (Japanese Patent Laid Open (kokai) Publication No. 2008-251138).

### BRIEF DESCRIPTION OF THE DRAWINGS

FIG. 1 is a block diagram showing an entire configuration of a NAND flash memory which is an example of a semiconductor memory device according to a first embodiment.

FIG. 2 is a block diagram showing a control unit according to the first embodiment.

FIG. 3 is a flowchart showing operations of a write sequence in the semiconductor memory device according to the first embodiment.

FIG. 4 is a flowchart showing operations of a read sequence in the semiconductor memory device according to the first embodiment.

FIG. 5 is a diagram showing a relationship between the threshold distribution of memory cells and the read voltage in a semiconductor memory device according to a comparative example.

FIGS. 6A, 6B are diagrams showing a relationship between the threshold distribution of memory cells and the read voltage in the semiconductor memory device according to the first embodiment.

FIG. 7 is a diagram showing a relationship between the threshold distribution of memory cells and the read voltage in a semiconductor memory device according to a modified example 1.

FIG. 8 is a diagram showing a first threshold distribution and a second threshold distribution in a threshold distribution of multiple memory cells.

FIG. 9 is a diagram showing a threshold distribution when a voltage lower than a voltage Vread by, for example, ΔVC is used as a voltage Vreadlow to read all levels.

FIG. 10 is a diagram showing a threshold distribution when a voltage lower than a voltage Vread by, for example, ΔVA is used as a voltage Vreadlow to read all levels.

FIG. 11 is a diagram showing operations of a read sequence in a semiconductor memory device according to a second embodiment.

### DETAILED DESCRIPTION

Embodiments of the present invention are described in detail with reference to the accompanying drawings. In the drawings of embodiments described hereinafter, same configurations are denoted by the same reference numerals to omit duplicate description. The dimensional proportions in the drawings are not limited to the illustrated proportions.

In general, according to one embodiment, a semiconductor memory device includes: a memory cell array including a plurality of memory cells; a first word line connected to a control gate of a first memory cell; a second word line connected to a control gate of a second memory cell and neighboring the first word line on one side; a third word line connected to a control gate of a third memory cell and neighboring the first word line on an opposite side to the one side; and a control circuit configured to read data from the first word line under a condition in which the memory cell connected to the second word line holds data while the memory cell connected to the third word line does not hold data, and set a first voltage applied to the third word line neighboring the first word line to be lower than a second voltage applied to the second word line neighboring the first word line on the opposite side of the third word line.

### First Embodiment

This embodiment is described by using a NAND flash memory, as an example of a semiconductor memory device, which uses memory cells of a multilayer gate structure. The semiconductor memory device is not limited to the NAND flash memory, but may be other semiconductor memory devices.

### [Configuration of NAND Flash Memory]

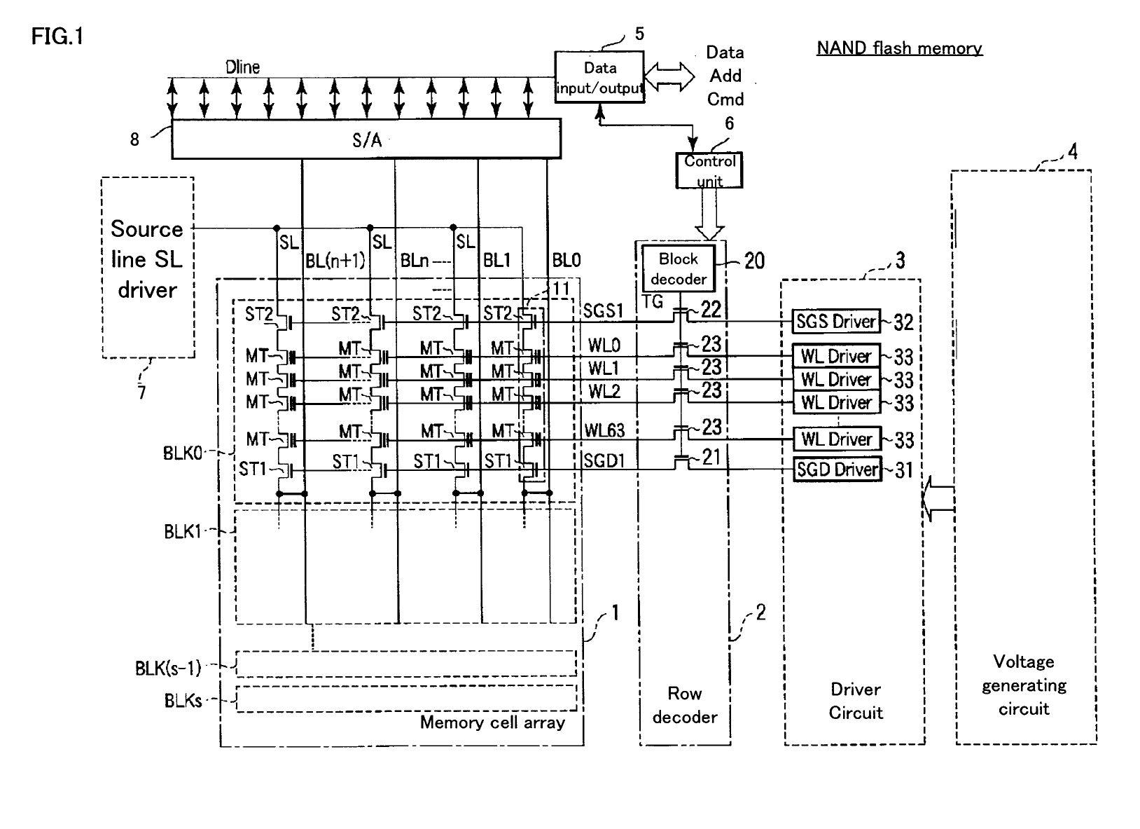

A NAND flash memory according to this embodiment is described with reference to FIG. 1. As shown in FIG. 1, the NAND flash memory includes a memory cell array 1, a row decoder 2, a driver circuit 3, a voltage generating circuit 4, a data input/output circuit 5, a control unit 6, a source line SL driver 7, and a sense amplifier (S/A) 8.

### Memory Cell Array

The memory cell array 1 includes blocks BLK0 to BLKs (s is a natural number), each of which includes multiple nonvolatile memory cells MT. Each of the blocks BLK0 to BLKs includes multiple NAND strings 11. Each of the NAND strings 11 includes multiple nonvolatile memory cells MT and select transistors ST1, ST2. As shown in FIG. 1, 64 memory cells are disposed between the select transistors ST1, ST2 such that current paths of the 64 memory cells are connected in series. A drain region at one end of the memory cells MT connected in series is connected with a source region of the select transistor ST1, and a source region at the other end of the memory cells MT is connected with a drain region of the select transistor 2. Memory cells MT neighboring each other share the source and the drain.

The number of memory cells MT connected in series is not limited to 64, but may be 128, 256, 512 or other numbers. The number is not limited.

The memory cell MT is capable of holding binary or multi-valued data. A structure of the memory cell MT is a MONOS structure which includes a charge storage layer (for example, an insulating film) formed on a semiconductor substrate via a gate insulating film, an insulating film (an insulating film having a dielectric constant higher than a dielectric constant of the charge storage layer) formed on the charge storage layer, and a control gate formed on the insulating film. The structure of the memory cell MT may be a FG type. The FG type is a structure which includes a floating gate (charge storage layer) formed on a p-type semiconductor substrate via a gate insulating film, and a control gate formed on the floating gate via a gate insulating film.

The control gate of the memory cell MT is electrically connected with a word line WL (WL0-WL63), the drain is electrically connected with a bit line BL (BL0-BL(n+1)), and the source is electrically connected with a source line SL.

Control gates of memory cells MT on a same row are commonly connected with any one of word lines WL0 to WL63, and gate electrodes of the select transistors ST1, ST2 of the memory cells on same rows are commonly connected with select gate wires SGD1, SGS1, respectively.

Further, drains of the select transistors ST1 on a same column in the memory cell array 1 are commonly connected with any one of bit lines BL0 to BLn. Sources of the select transistors ST2 are commonly connected with the source line SL.

Data is written into multiple memory cells MT connected with a same word line WL, all at once. This unit is called a page. Further, data of multiple memory cells MT is erased all at once on a per block BLK basis.

The memory cell array 1 has a ROMFUSE region (not shown). A range of memory cells into which input data is to be written is held in a table per block in the ROMFUSE region. Specifically, data is held by associating a block address and an indicator (for example, n is used as the indicator when data is held in the memory cells connected to word lines WL0 to WLn) with each other.

### <Row Decoder>

The row decoder 2 includes a block decoder 20 and transfer transistors 21 to 23 (n-channel MOS transistors). The block decoder 20 decodes a block address given by the control unit 6 in a data write, read or erase operation, and selects a block BLK on the basis of the result thereof. The block decoder 20 transfers a block select signal to transfer transistors 21 to 23, and thereby transfer transistors 21 to 23 are turned on. The row decoder 2 transfers voltages given by the driver circuit 3 to the select gate lines SGD1, SGS1 and the word lines WL0 to WL63, respectively.

### <Driver Circuit>

The driver circuit 3 includes select gate line drivers 31, 32 provided for the respective select gate lines SGD1, SGS1, and a word line driver 33 provided for each of the word lines WL. According to this embodiment, the word line driver 33 and the select gate line drivers 31, 32 are provided to each of the blocks BLK0 to BLKs.

In a data write, data read, data erase or data verify operation, the select gate line driver 31 transfers a signal sgd, for example, to a gate of the select transistors ST1 via the select gate line SGD1. The signal sgd is set to 0[V] when the signal is “L” level, and to VDD (for example 1.8[V]) when the signal is “H” level.

Similar to the select gate driver 31, in a data write, data read or data verify operation, the select gate driver 32 transfers a voltage required for the operation to a gate of the select transistors ST2 via a select gate SGS1 associated with a selected block BLK. The signal sgs is set to 0[V] when the signal is “L” level, and to VDD when the signal is “H” level.

### <Voltage Generating Circuit>

The voltage generating circuit 4 generates a voltage required for writing, reading or erasing data by boosting or reducing a voltage provided externally, and supplies a generated voltage to the driver circuit 3.

### <Data Input/Output Circuit>

The data input/output circuit 5 outputs an address or a command supplied from a host via an I/O terminal (not shown) to the control unit 6. Further, the data input/output circuit 5 outputs write data to the sense amplifier 8 via a data line Dline.

### <Control Unit>

The control unit 6 outputs the above block select signal to the row decoder 2. Further, the control unit 6 outputs a column select signal to the sense amplifier 8. The column select signal is a signal for selecting a column direction of the sense amplifier 8.

The control unit 6 is given a control signal supplied from a memory controller (not shown). The control unit 6 distinguishes according to the supplied control signal whether a signal supplied from a host to the data input/output circuit 5 via an I/O terminal (not shown) is the address or data.

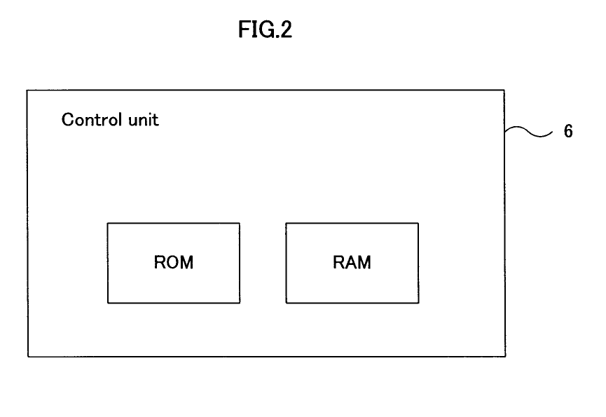

As shown in FIG. 2, the control unit 6 includes a ROM and a RAM. The control unit 6 holds a data capacity for one page in the ROM. The control unit 6 calculates a range of memory cells into which input data is to be written by using the data capacity for one page. Operations in a write sequence and a read sequence are described in detail later.

### Source Line SL Driver

The source line SL driver 7 operates according to an internal control signal received from the control unit 6. For example, in an erase operation, the source line SL driver 7 is controlled by the control unit 6 such that a voltage VDD is transferred from the source line SL to the bit line BL.

### <Sense Amplifier>

The sense amplifier 8 senses, amplifies and temporarily holds, in a read operation, data read from the memory cell array 1 and transfers the data to the data input/output circuit 5 via the data line Dline. In a write operation, the sense amplifier 8 transfers data transferred from the data input/output circuit 5 to the memory cell array 1 via the bit line BL.

### <Operations of Write Sequence>

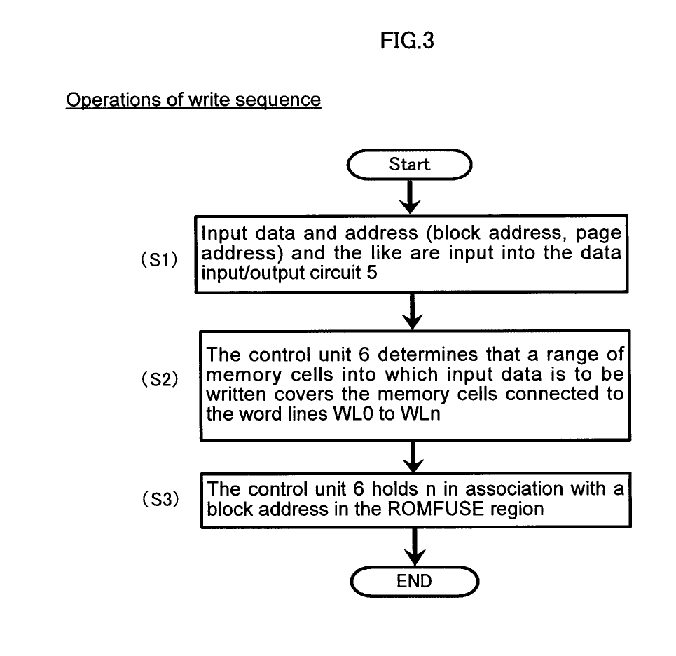

Operations of the NAND flash memory in the write sequence are described with reference to FIG. 3. For the sake of simplicity, a step of writing data into the memory cell is omitted from FIG. 3. The write operation is performed such that data is written into the memory cells connected to the word line WL0 and then is sequentially written into the memory cells connected to neighboring word lines WL in the order of the word lines WL1, WL2, WL3 . . . .

As shown in FIG. 3, first at Step S1, input data and address (block address, page address) and the like are input into the data input/output circuit 5.

Then, at Step S2, the control unit 6 temporarily holds input data and address, for example, in the ROM in the control unit 6. The control unit 6 reads out, into the RAM, a data capacity for one page held in the ROM and calculates, in a block designated by the block address, a range of memory cells into which input data is to be written. Specifically, the control unit 6 determines that a range of memory cells into which input data is to be written covers the memory cells connected to the word lines WL0 to WLn (n is a natural number), by dividing a data capacity of input data by the data capacity for one page.

At Step S3, the control units 6 holds, for example, in the ROMFUSE region of the memory cell array 1, a table in which n of the above word line WLn as an indicator showing the range of memory cells is associated with the block address.

Although the range of memory cells into which input data is to be written is calculated by using the data capacity at Step S2, the calculation method is not limited thereto. For example, the control unit 6 may calculate a range of memory cells into which input data has been written. Specifically, a latch circuit for flagging to indicate whether or not data is written is provided on each of the word lines WL. When input data is written into the memory cells of a word line WL in one page, data “0” is held in an associated latch circuit, and when input data is not written into the memory cells of a word line WL in one page, data “1” is held in an associated latch circuit. With setting of the flags in this manner, a range of memory cells into which input data is to be written can be calculated by reading data of a plurality of latch circuits for flagging.

Although at Step S3 the control unit 6 holds n in association with a block address, for example, in the ROMFUSE region, it is not limited thereto, but n may be held in the other register.

### <Operations of Read Sequence>

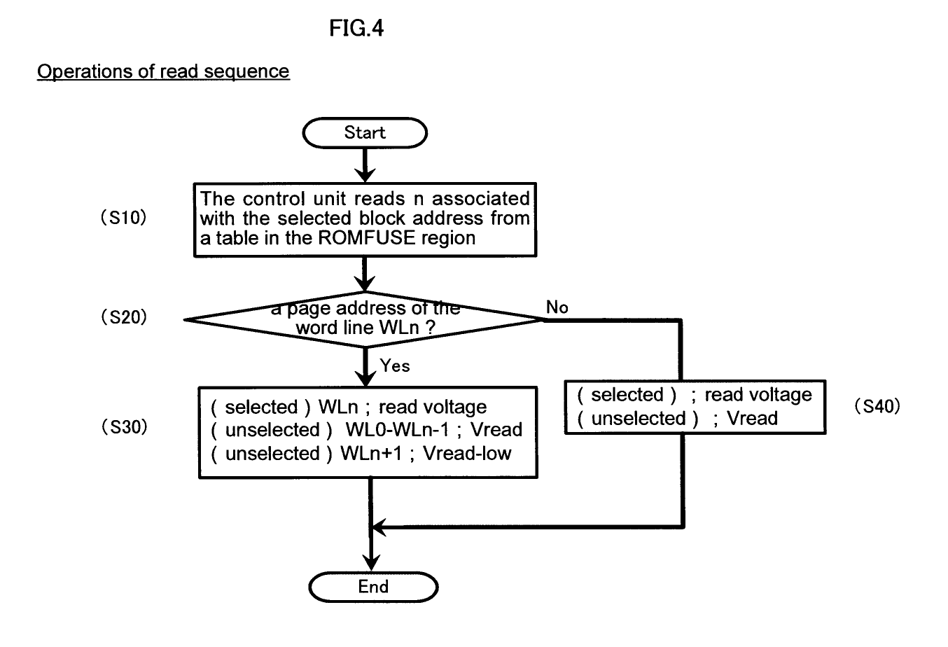

First, operations of the NAND flash memory in the read sequence are described with reference to a flowchart of FIG. 4.

First, at Step S10, the control unit 6 receives address (block address, page address) and the like via the data input/output circuit 5. The control unit reads n associated with the selected block address from a table in the ROMFUSE region, for example, a ROM.

At Step S20, the control unit 6 determines according to the input page address (page address to be read) whether or not a word line WL from which data is read is the word line WLn. Specifically, the control unit 6 determines whether or not the page address is identical with a page address of the word line WLn.

If it is determined that the page address is identical with a page address of the word line WLn (Step S20: Yes), the control unit 6 applies a read voltage (represented by VAR when reading the level A, by VBR when reading the level B, and by VCR when reading the level C, but subject to VAR<VBR<VCR) to the selected word line WLn (Step S30). Then, the control unit 6 applies a voltage Vread to the word lines WL0 to WL(n−1) out of the unselected word lines WL (Step S30), and applies a voltage Vreadlow to a word line WL(n+1) out of the unselected word lines WL (Step S30). Here, the voltage Vreadlow is a voltage lower than the voltage Vread by a given voltage. The given voltage may be, for example, a mean value of voltage differences corresponding to shifts of threshold distributions of the memory cells connected to the word lines WL0 to WL(n−1) from a threshold distribution of the memory cells connected to the word line WLn.

On the other hand, when it is determined that the page address is not identical with a page address of the word line WLn (Step S20: No), the control unit 6 applies a read voltage to a selected word line WL (any one word line WL out of the word lines WL0 to WL(n−1) (Step S40), and applies a voltage Vread to unselected word lines WL (Step S40).

### Effects of First Embodiment

The semiconductor memory device according to the first embodiment determines whether or not an input page address is identical with a page address of the word line WLn held in the table. When it is determined that the above two page addresses are identical with each other, the control unit 6 applies a read voltage to the selected word line WLn, and applies a voltage Vread to a word line WL(n+1) out of the unselected word lines WL.

In the write sequence, input data is written into the memory cells connected to a word line WL0 to the word line WLn. Thus, the memory cells holding data “0” and connected to any one of the word lines WL0 to WL(n−1) are subjected to a neighborhood effect when data is written into the memory cells connected to both neighboring word lines WL.

However, the memory cells holding data “0” and connected to the word line WLn are subjected to the neighborhood effect when data is written into the memory cells connected to a neighboring word line WL(n−1), but are not subjected to the neighborhood effect from the memory cells connected to a word line WL(n+1).

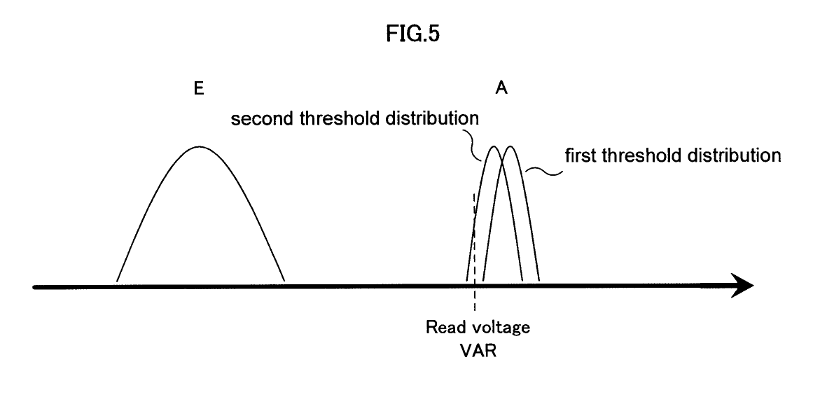

Therefore, as shown in a schematic diagram of FIG. 5, a threshold distribution (first threshold distribution) of the memory cells holding data “0” and connected to the word lines WL0 to WL(n−1) shifts to a positive side from the threshold distribution (second threshold distribution) of the memory cells holding data “0” and connected to the word line WLn. That is, the first threshold distribution becomes higher than the second threshold distribution. In FIG. 4, operations for levels B and C are omitted. Although a shifted second threshold distribution substantially overlaps the first threshold distribution, FIG. 5 shows the shifted second threshold distribution and the first threshold distribution by displacing each other for the convenience of simplicity.

As a comparative example, a semiconductor memory device is discussed that applies a voltage Vread to the unselected word lines WL in the read operation without determining whether or not a selected word line WL is the word line WLn. In this case, as shown in FIG. 4, a read voltage VAR1 is lower than the first threshold distribution, but is not lower than the second threshold distribution. As a result, data of the memory cells having the second threshold distribution may be read erroneously in some cases.

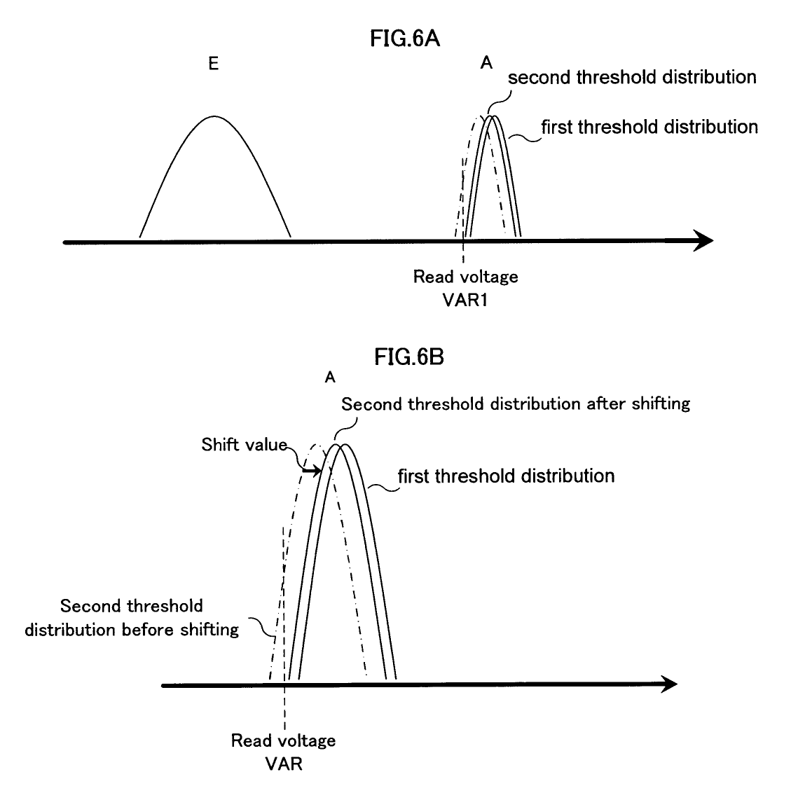

However, the semiconductor memory device according to the present embodiment can apparently shift a threshold distribution of the memory cells holding data “0” and connected to the word line WLn to a positive side (with the threshold distribution shifting from the dotted line to the solid line) by applying a voltage Vreadlow to a word line WL(n+1) out of the unselected word lines WL, as shown in FIGS. 6A, 6B. As a result, a threshold distribution of the memory cells holding data “0” and connected to the word line WLn can be brought closer to the first threshold distribution.

In such a manner, erroneous data reading can be reduced even when a read voltage used to read data of the memory cells connected to the word lines WL0 to WL(n+1) is used to read data of the memory cells connected to the word line WLn.

As described above, the semiconductor memory device according to the present embodiment is capable of reducing an erroneous read.

### Modified Example 1

The semiconductor storage apparatus according to the first embodiment applies a voltage Vreadlow to a word line WL(n+1) out of the unselected word lines WL when reading data of the word line WLn. A semiconductor memory device according to a modified example 1 is different when reading multi-valued data in that the control unit 6 controls a voltage VreadAlow applied to the word line WL(n+1) when reading a level A, a voltage VreadBlow applied to a word line WL(n+1) when reading a level B, and a voltage VreadClow applied to a word line WL(n+1) when reading a level C. Other configurations and operating methods are the same as in the first embodiment.

All of the voltages VreadAlow, VreadBlow, and VreadClow are voltages lower than a voltage Vread, and voltage differences thereof from the voltage Vread are ΔVA, ΔVB and ΔVC respectively.

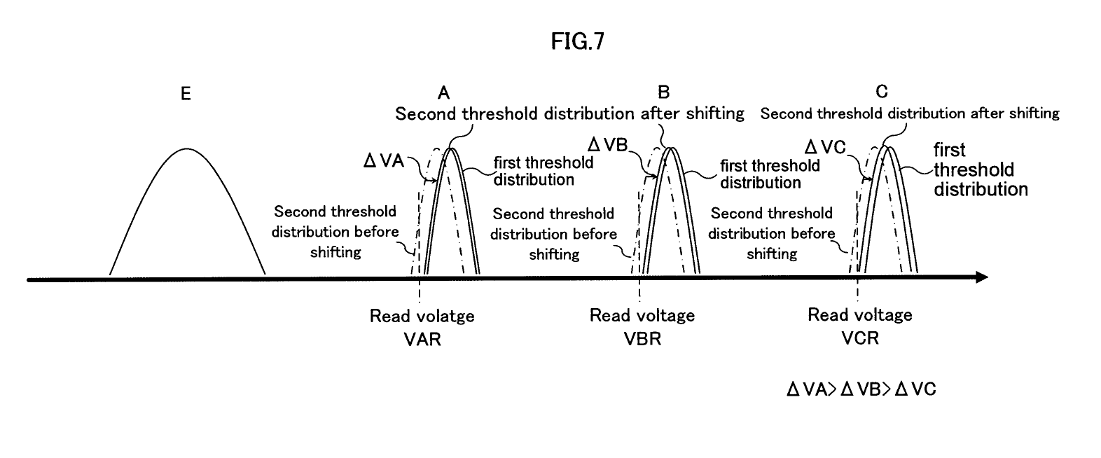

For example, as shown in FIG. 7, ΔVA, ΔVB and ΔVC are set so as to satisfy a formula (I) shown below.

ΔVA>ΔVB>ΔVC (1)

In the modified example 1, ΔVA, ΔVB and ΔVC are held, for example, in the ROMFUSE region. The control unit 6 reads data indicating ΔVA, ΔVB or ΔVC held in the ROMFUSE region in the memory cell array 1, and controls a voltage applied to a word line WL(n+1) according to the read level. Specifically, the control unit 6 outputs an internal control signal to the voltage generating circuit 4 and controls the voltage generating circuit 4 so that a predetermined voltage is applied (for example, if the read level is the level A, a voltage VreadAlow is applied).

### Effects of Modified Example 1

A semiconductor memory device according to the modified example 1 provides similar effects to a semiconductor memory device according to the first embodiment. The present inventor verified in experiments that a difference between the first threshold distribution and the second threshold distribution becomes smaller in the order of Level A, Level B and Level C. That is, ΔVA>ΔVB>ΔVC was verified in experiments.

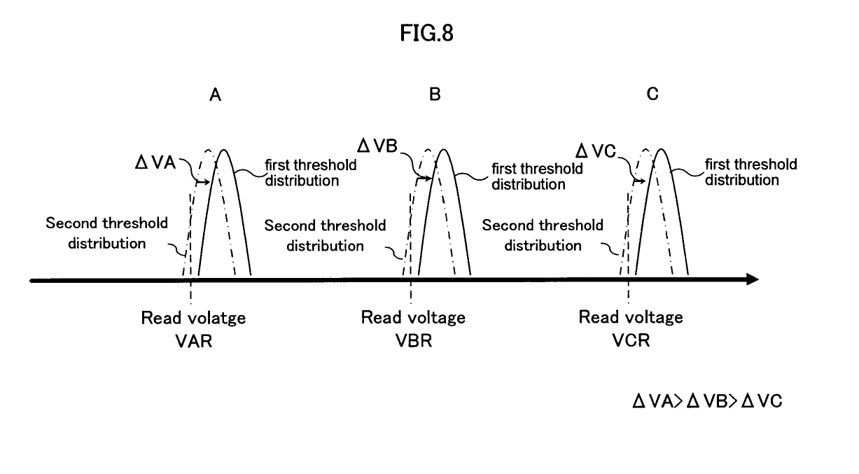

For example, assume that as in the first embodiment, a voltage lower than the voltage Vread by, for example, ΔVC is used as a voltage Vreadlow for reading all levels including levels A, B and C. In this case, as shown in FIG. 8, a threshold voltage correction amount in levels A and B becomes smaller, while the effect of reducing erroneous reading of levels A and B becomes smaller in some cases.

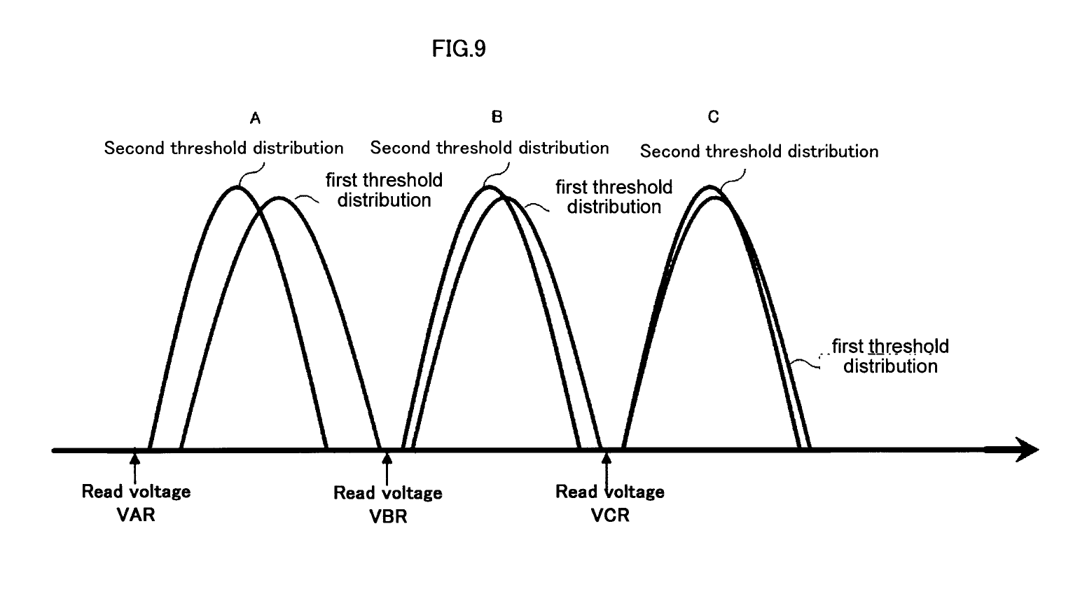

On the other hand, assume that a voltage lower than the voltage Vread by, for example, ΔVA is used as a voltage Vreadlow for reading all levels including levels A, B and C. In this case, as shown in FIG. 9, a correction amount of the threshold voltage in levels B and C becomes larger, the second threshold distribution shifts to a position higher than the first threshold distribution, and as a result, erroneous reading occurs at levels B and C in some cases. For example, when a memory cell configured to have a threshold voltage of the level B has a threshold voltage of the level C, erroneous reading occurs in some cases.

Thus, in the modified example 1, the voltage Vreadlow is varied according to the levels A, B and C so as to make the first threshold distribution and the second threshold distribution closer to each other compared with the first embodiment, whereby erroneous reading may be reduced further than in the first embodiment.

### Second Embodiment

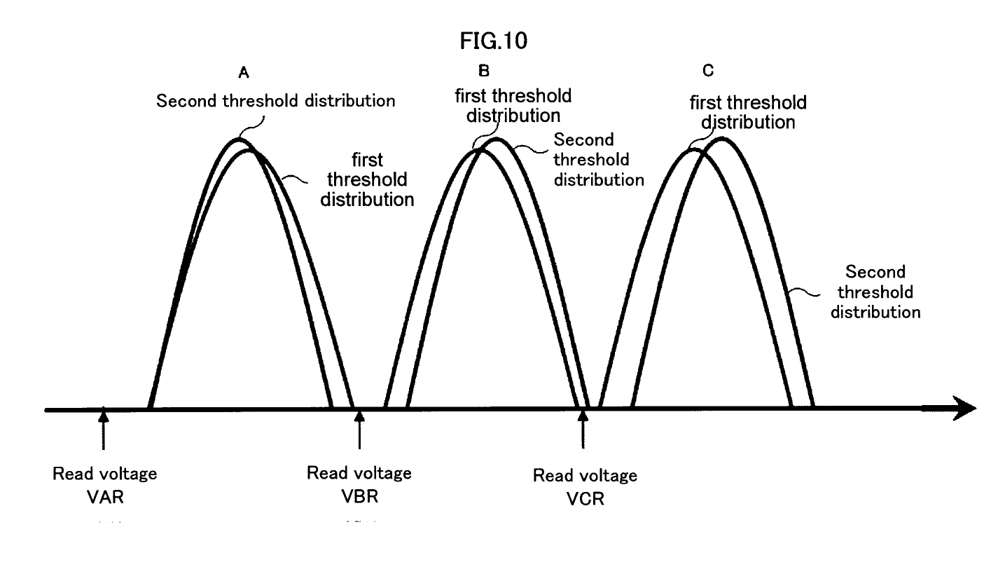

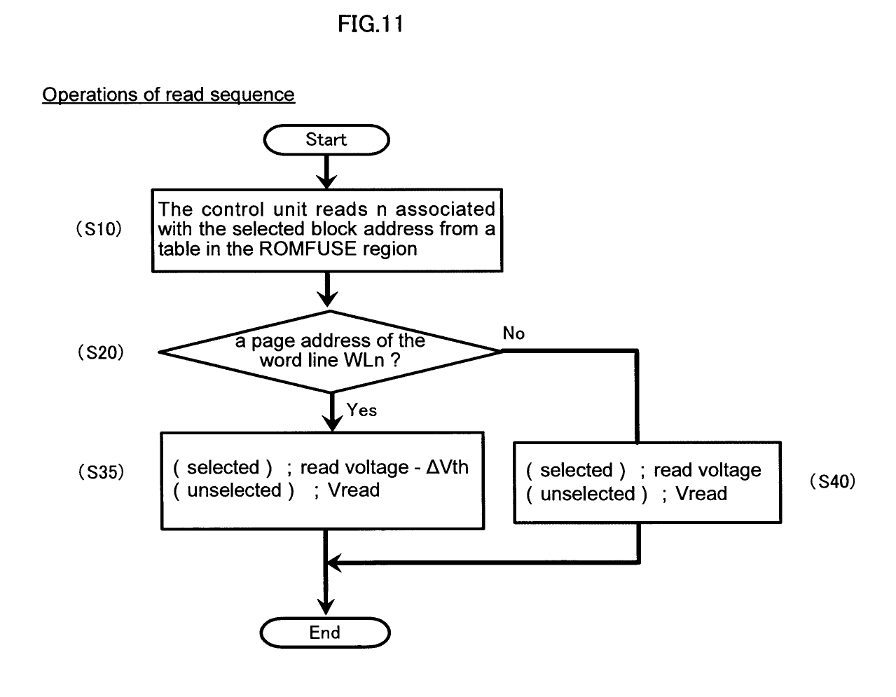

In the first embodiment, at Step S30, a read voltage is applied to a selected word line WLn, and a voltage Vread is applied to the word lines WL0 to WL(n−1) out of the unselected word lines. The second embodiment is different from the first embodiment in that in the second embodiment, as shown in FIGS. 10 and 11, a voltage calculated by a read voltage minus a given voltage is applied to a selected word line WLn, and a voltage Vread is applied to the unselected word lines WL, see Step S35. Other configurations and operations are the same as those of the first embodiment.

Here, the voltage calculated by a read voltage minus a given voltage AVth is a voltage calculated by the read voltage minus a mean value of voltage differences corresponding to shifts of the threshold distributions of the word lines WL0 to WL(n−1) from the threshold distribution of the word line WLn.

Thus, erroneous reading can be reduced by changing a voltage applied to a selected word line WL from a read voltage without changing a voltage applied to unselected word lines WL.

The modified example 1 may be combined with the second embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell array including a plurality of memory cells,
a first word line connected to a control gate of a first memory cell;
a second word line connected to a control gate of a second memory cell and neighboring the first word line on one side;
a third word line connected to a control gate of a third memory cell and neighboring the first word line on an opposite side to the one side; and
a control circuit configured to read data from the first word line under a condition in which the memory cell connected to the second word line holds data while the memory cell connected to the third word line does not hold data, and to set a first voltage applied to the third word line neighboring the first word line to be lower than a second voltage applied to the second word line neighboring the first word line on the opposite side of the third word line.

2. The semiconductor memory device according to claim 1, wherein
the control circuit identifies the first word line by calculating a range of memory cells to which data is to be written in the memory cell array, and stores a flag indicating the first word line into a storage region.

3. The semiconductor memory device according to claim 2, wherein
in a data read sequence, the control circuit reads the flag stored in the storage region, and sets the first voltage to be lower than the second voltage when the word line connected to a memory cell from which data is to be read is the first word line.

4. The semiconductor memory device according to claim 2, wherein
in a data read sequence, the control circuit reads the flag stored in the storage region, and sets the first voltage to be same as the second voltage when the word line connected to a memory cell from which data is to be read is the first word line.

5. The semiconductor memory device according to claim 1, wherein
for reading data from a memory cell of a read target connected to the first word line under a condition in which the memory cells each hold multi-value data, the control circuit sets a voltage difference between the second voltage and the first voltage for use to read data at a level A, to be lower than a voltage difference between the second voltage and the first voltage for use to read data at a different level B.

6. The semiconductor memory device according to claim 2, wherein
for reading data from a memory cell of a read target connected to the first word line under a condition in which the memory cells each hold multi-value data, the control circuit sets a voltage difference between the second voltage and the first voltage for use to read data at a level A, to be lower than a voltage difference between the second voltage and the first voltage for use to read data at a different level B.

7. The semiconductor memory device according to claim 1, wherein
for reading data from a memory cell of a read target connected to the first word line under a condition in which the memory cells each hold multi-value data, the control circuit sets a voltage difference between the second voltage and the first voltage for use to read data at a level B, to be lower than a voltage difference between the second voltage and the first voltage for use to read data at a different level C.

8. The semiconductor memory device according to claim 2, wherein
for reading data from a memory cell of a read target connected to the first word line under a condition in which the memory cells each hold multi-value data, the control circuit sets a voltage difference between the second voltage and the first voltage for use to read data at a level B, to be lower than a voltage difference between the second voltage and the first voltage for use to read data at a different level C.

9. The semiconductor memory device according to claim 2, wherein
when data is sequentially written to the memory cells connected to the word lines selected one by one in ascending or descending order, the word line selected at the end of data write is determined as the first word line, and a number of the word line selected at the end of data write is held in the storage area.

10. The semiconductor memory device according to claim 3, wherein
when data is sequentially written to the memory cells connected to the word lines selected one by one in ascending or descending order, the word line selected at the end of data write is determined as the first word line, and a number of the word line selected at the end of data write is held in the storage area.

11. A semiconductor memory device comprising:
a memory cell array including a plurality of memory cells;
a plurality of word lines connected to control gates of the memory cells, wherein
for reading data from a first word line under conditions in which a memory cell connected to a second word line neighboring the first word line on one side holds data while a memory cell connected to a third word line neighboring the first word line on an opposite side to the one side does not hold data, a voltage applied to the first word line is set to be lower than a voltage applied to a fourth word line for reading data from the fourth word line under a condition in which memory cells connected to both word lines neighboring the fourth word line hold data.

12. The semiconductor memory device according to claim 11, wherein
the control circuit identifies the first word line by calculating a range of memory cells to which data is to be written in the memory cell array, and stores a flag indicating the first word line into a storage region.

13. The semiconductor memory device according to claim 12, wherein
in a data read sequence, the control circuit reads the flag stored in the storage region, and sets the first voltage to be lower than the second voltage when the word line connected to a memory cell from which data is to be read is the first word line.

14. A semiconductor memory device comprising:
a memory cell array including a plurality of memory cells;
a first word line connected to a control gate of a first memory cell;
a second word line connected to a control gate of a second memory cell and neighboring the first word line on one side;
a third word line connected to a control gate of a third memory cell and neighboring the first word line on an opposite side to the one side; and
means for controlling to read data from the first word line under a condition in which the memory cell connected to the second word line holds data while the memory cell connected to the third word line does not hold data, and to set a first voltage applied to the third word line neighboring the first word line to be lower than a second voltage applied to the second word line neighboring the first word line on the opposite side of the third word line.
